(19) United States
(12) Patent Application Publication
(10) Pub. No.: US 2026/0128761 A1
(43) Pub. Date: May 7, 2026

(54) OPEN SYSTEMS ARCHITECTURE TACTICAL RADIO INTERFERENCE IMPROVEMENT

(71) Applicant: Rockwell Collins, Inc., Cedar Rapids, IA (US)

(72) Inventors: Jeffrey D. GRUNDMEYER, Walker, IA (US); John V. THOMMANA, Garland, TX (US)

(73) Assignee: Rockwell Collins, Inc., Cedar Rapids, IA (US)

(21) Appl. No.: 18/936,570

(22) Filed: Nov. 4, 2024

(51) Int. Cl. H04B 1/52; H03G 3/30; H04B 1/00; H04B 1/44

(52) U.S. Cl. CPC H04B 1/52; H03G 3/3078; H04B 1/0057; H04B 1/44

(57) ABSTRACT

A multi-band filtering transceiver includes a multi-band antenna, a transceiver switch, transmission circuitry, receive circuitry, a multiplexer coupled to the transmission circuitry and the receive circuitry. The multiplexer outputs a signal of interest in accordance with an open standard protocol. The receive circuitry includes a bandpass filter coupled to the receiving port of the transceiver switch, a low noise amplifier having an input coupled to the bandpass filter, a band separation circuit coupled to an output of the low noise amplifier. The band separation circuit is operative to output a full spectrum signal corresponding to the entire frequency band and a first sub-band signal corresponding to a first portion of the entire frequency band. A full band circuit to receive the full spectrum signal and a first sub-band circuit first sub-band signal. The full spectrum signal and the first sub-band signal are simultaneously transmitted to the multiplexer for downstream processing.

### FIELD OF THE INVENTION

The subject matter disclosed herein relates to radio communication and, in particular, to cosited antenna communication.

### BACKGROUND OF THE INVENTION

Wideband receivers used in Open Systems Architecture (OSA) Multi-functional Apertures (MFA) for tactical radio waveforms provide tremendous flexibility to operate different waveforms and multiple channels simultaneously in comparison to traditional narrowband receivers in legacy radios. However, they lack the same receiver selectivity performance that legacy receivers have in hardware implementations such as superheterodyne receiver designs. The receiver performance is restricted by the dynamic range of currently available analog to digital converter devices. This issue severely limits the MFA from operating at full sensitivity when operating in a dense cosite environment such as multiple channels operating on a single vehicle or aircraft.

### SUMMARY OF THE INVENTION

The present disclosure is directed, in a first aspect, to a multi-band filtering transceiver that includes a multi-band antenna, a transceiver switch, transmission circuitry, receive circuitry, a multiplexer coupled to the transmission circuitry and the receive circuitry, operative to output a signal of interest in accordance with an open standard protocol. In particular, the receive circuitry is coupled to the transceiver switch and is operative to receive an entire frequency band. The receive circuitry includes a bandpass filter coupled to the receiving port of the transceiver switch, a low noise amplifier having an input coupled to the bandpass filter, a band separation circuit coupled to an output of the low noise amplifier. The band separation circuit is operative to output a full spectrum signal corresponding to the entire frequency band and a first sub-band signal corresponding to a first portion the entire frequency band. A full band circuit to receive the full spectrum signal and a first sub-band circuit first sub-band signal. The full spectrum signal and the first sub-band signal are simultaneously transmitted to the multiplexer for downstream processing.

In yet another embodiment, the present disclosure is directed to a cosited transceiver system having N transceivers, wherein N>1. At least one of the N transceivers includes a multi-band antenna, a transceiver switch, transmission circuitry, receive circuitry, a multiplexer coupled to the transmission circuitry and the receive circuitry, operative to output a signal of interest in accordance with an open standard protocol. In particular, the receive circuitry is coupled to the transceiver switch and is operative to receive an entire frequency band. The receive circuitry includes a bandpass filter coupled to the receiving port of the transceiver switch, a low noise amplifier having an input coupled to the bandpass filter, a band separation circuit coupled to an output of the low noise amplifier. The band separation circuit is operative to output a full spectrum signal corresponding to the entire frequency band and a first sub-band signal corresponding to a first portion of the entire frequency band. A full band circuit to receive the full spectrum signal and a first sub-band circuit first sub-band signal. The full spectrum signal and the first sub-band signal are simultaneously transmitted to the multiplexer for downstream processing.

In yet another embodiment, the present disclosure is directed to a receiving method for a transceiver. A full band signal corresponding to an entire frequency band received by the transceiver. Next, the full band signal is separated to provide a full spectrum signal corresponding to the entire frequency band and a first sub-band signal corresponding to a first portion of the entire frequency band. Next, the full spectrum signal and the first sub-band signal are simultaneously transmitted. In accordance with an open standard protocol, a signal of interest is produced.

### BRIEF DESCRIPTION OF FIGURES

The features of the disclosure believed to be novel and the elements characteristic of the invention are set forth with particularity in the appended claims. The figures are for illustration purposes only and are not drawn to scale. The disclosure itself, however, both as to organization and method of operation, can best be understood by reference to the description of the preferred embodiment(s) which follows, taken in conjunction with the accompanying drawings in which:

FIG. 1 illustrates the antennas available on a fighting vehicle according to the disclosed embodiments.

FIG. 2 illustrates the isolation between the four antennas as seen by the radio according to the disclosed embodiments.

FIG. 3 illustrates a VHF direct sampling MFA in the presence of a large interfering signal according to the disclosed embodiments.

FIG. 4 illustrates when the MFA of FIG. 3 encounters a strong nearby signal that is present in-band according to the disclosed embodiments.

FIG. 5 illustrates an MFA solution operating with a typical tri-band antenna solution in accordance that incorporates our method to maintain one channel at full sensitivity in each of the bands according to the disclosed embodiments.

FIG. 6A illustrates the band separation circuit and a receive circuit for a VHF band antenna according to the disclosed embodiments. FIG. 6B illustrates a receive circuit for an antenna that receives multiple ranges and the band separation circuit according to the disclosed embodiments.

FIG. 7 illustrates an MFA approach operating with a tri-band antenna that maintain one channel at full sensitivity in each of the bands.

FIG. 8 illustrates a graph 800 showing the sub-band filtering ahead of the ADC reduces S4, along with other channel signals S1 and S3 while preserving the SNR of S2.

### DETAILED DESCRIPTION OF THE INVENTION

The embodiments of the present disclosure can comprise, consist of, and consist essentially of the features and/or steps described herein, as well as any of the additional or optional ingredients, components, steps, or limitations described herein or would otherwise be appreciated by one of skill in the art. It is to be understood that all concentrations disclosed herein are by weight percent (wt. %.) based on a total weight of the composition unless otherwise indicated.

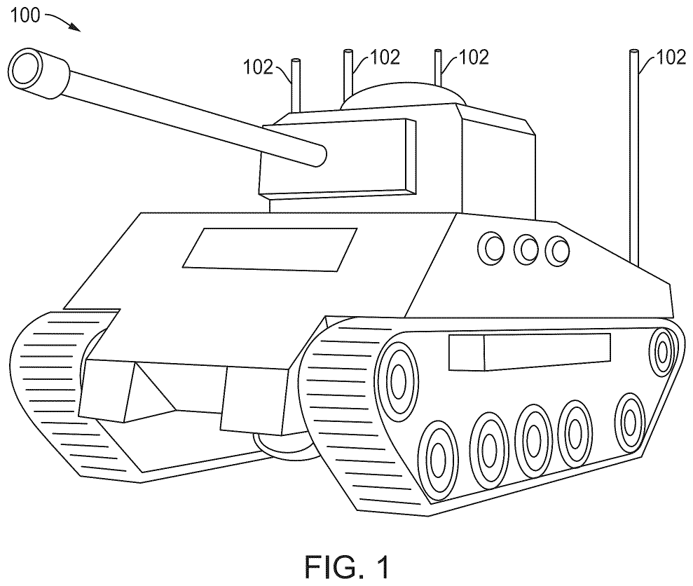

FIG. 1 illustrates the antennae available on a fighting vehicle 100. There are four tri-band antennas 102, for example, COMROD VHF302600 TB-F. The COMROD VHF302600 TB-F is a tri-band (VHF/UHF/L-S Band antenna). Within the antenna, the three elements of the tri-band antenna are connected via a triplexer (VHF/UHF/L-S) to traditional manpack radios, e.g. networking ground radios.

A 50 Watt transmitter is used in VHF band to close the link at the ranges needed to operate in a tactical environment.

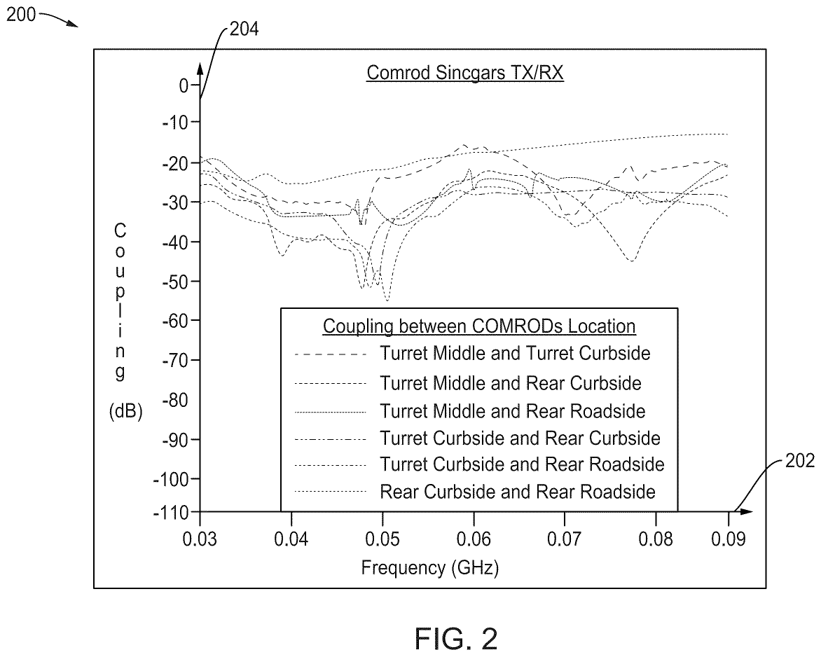

FIG. 2 illustrates a graph 200 of the isolation between the four antennas as seen by the radio. Axis 202 relates to frequencies operating in the 30-88 MHz range, expressed in GHz. Axis 204 relates to the coupling in decibels (dB). On average, there is 25 dB of isolation between an onboard transmit antenna to the other receive antennas on the platform. For an average 25 dB isolation in the VHF band, the interferer signal at the receiver, e.g. Radiohead, is on the order of +18 dBm. To receive a signal at sensitivity (−110 dBm), the dynamic range desired is 128 dB. Modern direct sampling receivers typically provide a dynamic range of approximately 100 to 110 dB. To successfully receive a signal at sensitivity a direct sampling receiver needs an additional 18 to 28 dB of cosite protection.

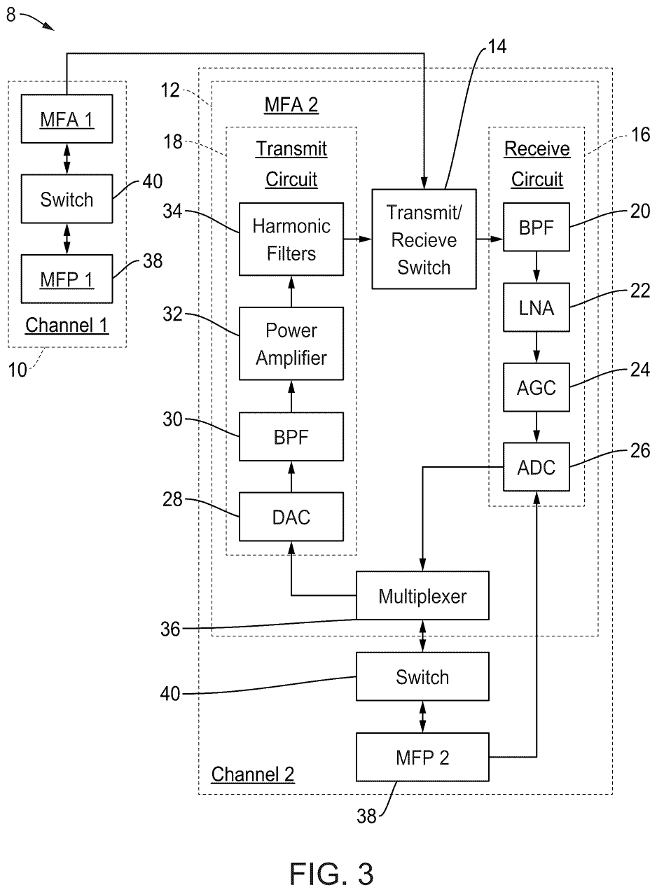

FIG. 3 illustrates a VHF Direct Sampling MFA 8 in the Presence of a Large Interfering Signal having a channel 1 (first VHF band antenna) 10 and a channel 2 (second VHF band antenna) 12. The Open Systems Architecture (OSA) based solution is installed on a platform with multiple Multi-functional Apertures (MFAs) and multi-function processors (MFPs) to support multiple tactical radio communications channels simultaneously. The architecture of the MFAs supports transmit and receive functionality for half duplex waveforms. While the VHF band is illustrated, the concept applies to the UHF and L & S bands.

A conventional VHF band MFA 12 includes a transmit/receive switch 14 coupled to a receive circuit 16 and a transmit circuit 18. The receive circuit 16 includes a first bandpass filter (BPF) 20 for the selected range, e.g. 30-174 MHz, a low noise amplifier (LNA) 22, and automatic gain control (AGC) 24, and an analog-to-digital converter 26. The transmit circuit 18 includes digital-to-analog converter (DAC) 28, a second bandpass filter 30, a power amplifier 32, and harmonic filters 34. A multiplexer 36 is coupled to the receive circuit 16 and the transmit circuit 18. A multi-function processor 38 is coupled to a switch 38 and to the AGC 24. The switch 40 is coupled to the multiplexer 36.

The receive circuit 16 has a typical direct sampling VHF MFA approach with a single receive circuit and wideband analog to digital conversion. This allows digital sampling of the VHF RF spectrum with signal levels up to the point where the analog-to-digital converter (ADC) becomes saturated or the low noise amplifier (LNA) goes into compression. To prevent the saturation of the ADC, the MFP must apply automatic gain control (AGC), e.g. attenuation, in the receive circuit, which will reduce the received signal strength of all the signals in the band and the ability to receive small signals.

One scenario is when Channel 1 (MFA 1 & MFP 1) 12 is transmitting a VHF signal at one frequency while Channel 2 (MFA 2 & MFP 2) is trying to receive a weak signal from a tactical radio at long distance on a second frequency.

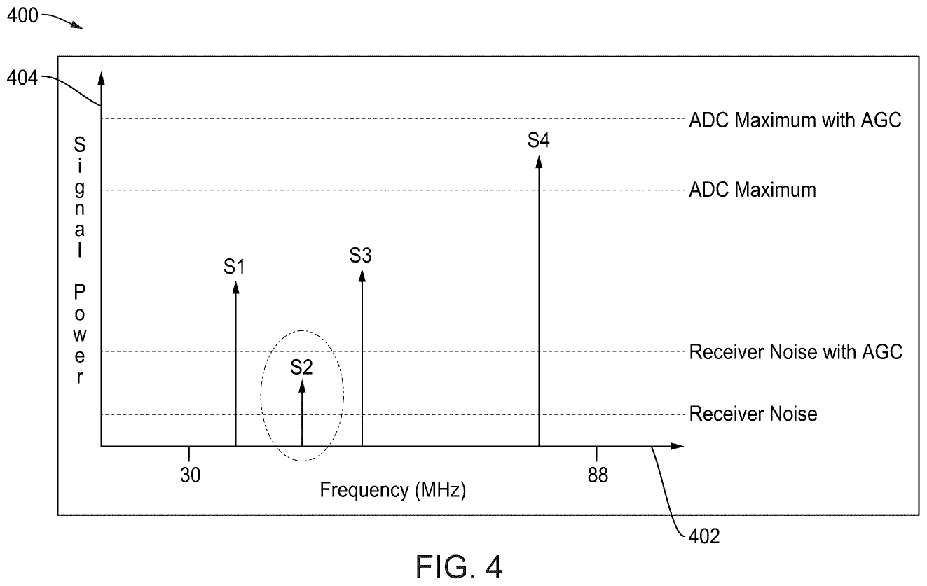

FIG. 4 illustrates a graph 400 when the MFA of Channel 2 (shown in FIG. 3) encounters a strong nearby signal that is present in-band. Axis 402 relates to the frequency in MHz. Axis 404 relates to signal power. Signals S1, S2, and S3 are the desired signals to demodulate in the MFP. When S4 is not present, all signals have sufficient signal-to-noise (SNR) to be received. When S4 is present (our co-located VHF transmitter on the same vehicle for example), the signal saturates the MFA ADC. The only recourse is to apply AGC to reduce all the in-band signals. But this reduces the received signal strength of S2 (the signal of interest) where it can no longer be received.

The disclosed embodiments implement an MFA solution operating with a typical tri-band antenna solution that maintains one channel at full sensitivity in each of the bands. While only a single receive circuit is shown to simplify the diagram, the MFA may include multiple sub-band receive circuits, e.g. one for each independent frequency band of interest. Having at least one sub-band circuit in parallel with the full circuit allows the WB receivers to be able to apply AGC to receive signals S1 and S3 in this case, while the sub-band filtering is applied to the sub-band circuit to receive the small signal, S2, simultaneously. The dual band filtering antenna is a multiband, multi-element aperture with 3 RF ports. It covers the primary bands for military tactical ground and air communications, which include VHF (30-174 MHz), UHF (225-941 MHz) and L and S-bands (banded ranges covering 1250-2700 MHz).

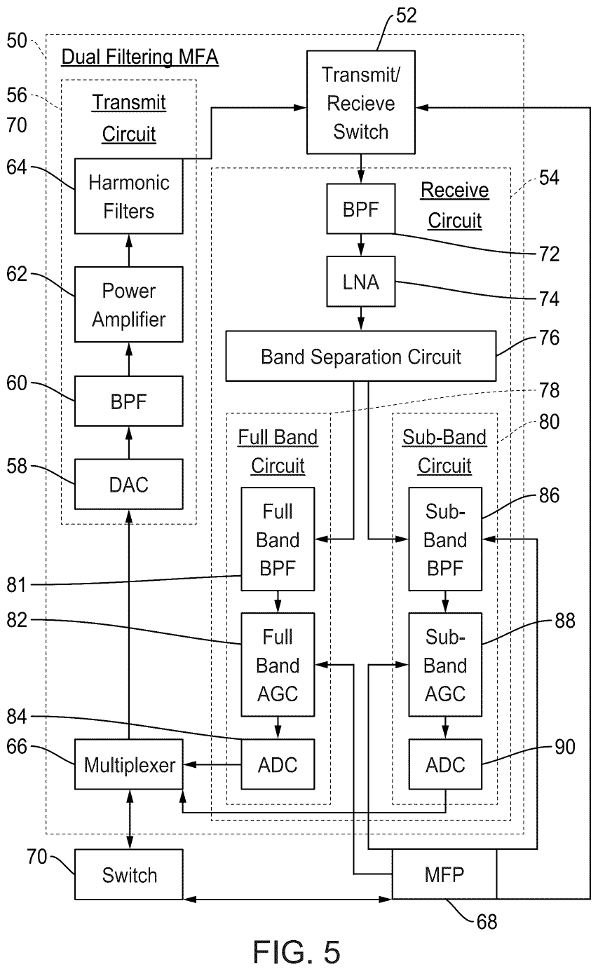

FIG. 5 illustrates a dual filtering MFA 50 including a transmit/receive switch 52 coupled to a receive circuit 54 and a transmit circuit 56. The transmit circuit 56 includes digital-to-analog converter (DAC) 58, a transmit bandpass filter 60, a power amplifier 62, and harmonic filters 64. A multiplexer 66 is coupled to the receive circuit 54 and the transmit circuit 56. A multi-function processor (MFP) 68 is coupled to a switch 70.

The receive circuit 54 includes a first bandpass filter (BPF) 72 for the selected range, e.g. 30-174 MHz, a low noise amplifier (LNA) with high compression point 74, a band separation circuit 76, a full band circuit 78, and at least one sub-band circuit 80. The output of the band separation circuit 76 are coupled to provide inputs for the full band circuit 78 and one for each sub-band circuit 80. The receive signal passes out of the antenna through the first band pass filter 72 passing the full frequency band range and rejects out-of-band signals. This feature protects the low noise amplifier (LNA) 74 from becoming saturated from strong out-of-band signals. The LNA 74 amplifies the signals to compensate for down-stream RF losses and establishes a low noise figure performance for the receiver system. The LNA 74 must have a high compression point to remain linear in the presence of the large signal levels.

The full band circuit 78 includes a full band bandpass filter (BPF) 81 for the selected range, e.g. 30-174 MHz, full band automatic gain control circuit (AGC) 82, and an analog-to-digital converter ADC 84. The analog-to-digital converter 84 is coupled to the multiplexer 66. The full band filter 80 provides RF protection to prevent out-of-band signals from entering the ADC 84. Following the full band bandpass filter 81, multi-function processor 66 controls the full band automatic gain control circuit 82 to achieve variable RF attenuation. The ADC 84 samples the attenuated RF signal and passes digital samples, using either VITA49.2 or MORA 2.5 standards for IQ Signal transport, via Ethernet fiber to the MFP 66 for processing.

The sub-band circuit 80 includes a sub-band bandpass filter 86 for the selected range, e.g. 30-174 MHz, a sub-band automatic gain control circuit (AGC) 88, and an analog-to-digital converter 90. The analog-to-digital converter 90 is coupled to the multiplexer 66. The tunable sub-band filter 86 rejects off channel signals from interfering with the ADC 90. This tunable BPF bandwidth can be as narrow as 2-3 percent or wider depending on the selectively needed for the application. The multi-function processor 66 controls the sub-band automatic gain control circuit 88 to achieve attenuation in the event the sub-band signal is also strong. The ADC 90 samples the sub-band RF signal and passes digital samples via Ethernet fiber to the MFP 66 for processing. Because the bandwidth of interest is as narrow as 1 MHz, a much lower ADC sampling rate can be used to conserve power and data bandwidth compared the full band circuit sampling.

The sampled spectrum, e.g. full band signal and sub-band signals, is then processed in the MFP 66 for each full band and each sub-band channel. This includes digital filtering and demodulation for the desired channels.

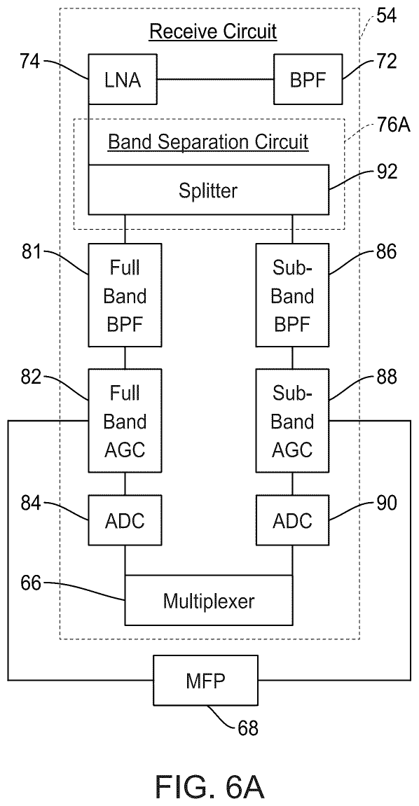

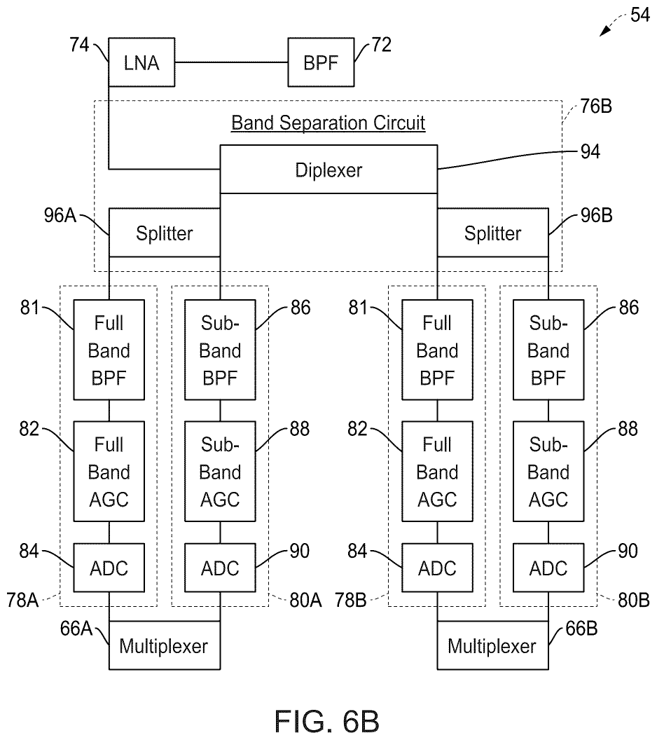

FIGS. 6A-6B illustrate embodiments of the band separation circuit 76 and the receive circuit 54.

FIG. 6A illustrates the band separation circuit 76A and a receive circuit 54 for a VHF band antenna. In this embodiment, the band separation circuit 76A is a replicating splitter 92. The replicating splitter has a first output operative to produce full band signals within the frequency range and a second output operative to produce a sub-band signal at a selected frequency within the frequency range.

In operation, the full band bandpass filter (BPF) 81 receives the full band signals. The multi-function processor 68 adjusts the full band automatic gain control circuit (AGC) 82. The analog-to-digital converter 84 digitizes the adjusted full band signals. The analog-to-digital converter 84 is coupled to the multiplexer 66.

In operation, the sub-band bandpass filter (BPF) 86 receives the sub-band signal. The multi-function processor 68 adjusts the sub-band automatic gain control circuit 88. The analog-to-digital converter 90 digitizes the adjusted sub-band signal.

FIG. 6B illustrates a receive circuit 54 for an antenna that receives multiple ranges and the band separation circuit 76B. The first bandpass filter (BPF) 72 for the entire range, e.g. 225-941 MHz, coupled to the low noise amplifier (LNA) 74. The band separation circuit 76B is a diplexer 94 that separates the UHF range into at least two sub-bands of interest, e.g. 225-450 MHz (military) and 470-941 MHz (commercial), and a corresponding replicating splitter 96A, 96B. Similarly, this configuration may be used separate the L and S communication bands.

Each replicating splitter 96A, 96B is coupled to a full band circuit 78A, 78B and a sub-band circuit 80A, 80B as illustrated in FIG. 6A. Similarly, each pair of full band circuit and sub-band circuit (78A, 80A) (78B, 80B) are respectively coupled a multiplexer 66A, 66B.

The full band circuits 78A, 78B and the sub-band circuits 80A, 80B have a typical direct sampling VHF MFA approach with a single receive circuit and full band analog-to-digital conversion. This feature allows digital sampling of the VHF RF spectrum with signal levels up to the point where the analog-to-digital converter (ADC) becomes saturated or the low noise amplifier (LNA) goes into compression. To prevent the saturation of the ADC, the MFP must apply automatic gain control (AGC), e.g. attenuation, in the receive circuit, which will reduce the signal-to-noise ratio and the ability to receive small signals.

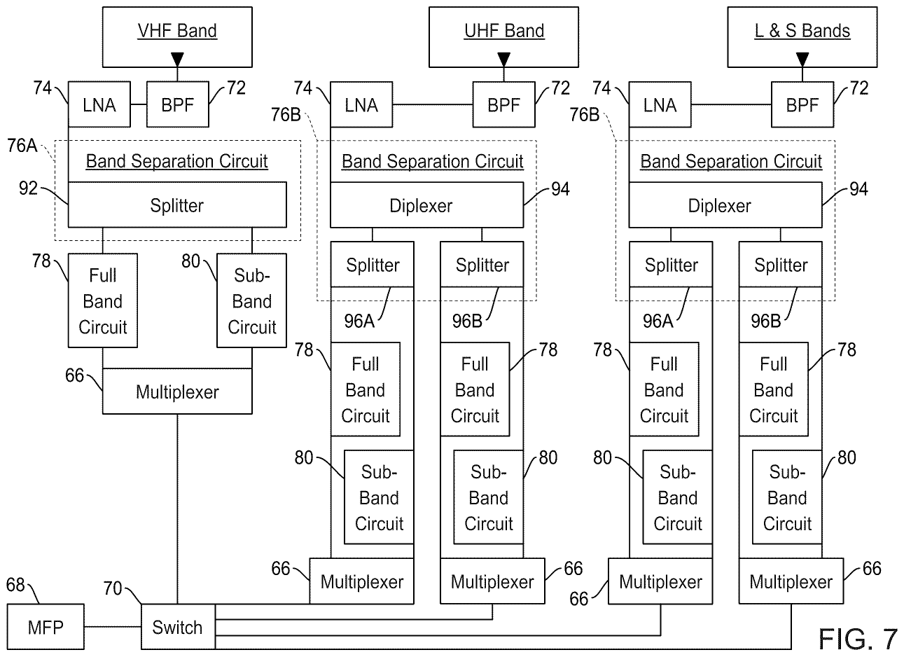

FIG. 7 illustrates an MFA approach operating with a tri-band antenna that maintain one channel at full sensitivity in each of the bands. Only the receive paths are shown to simplify the diagram, the MFA can operate transmit paths for each independent frequency band. The tri-band antenna can receive the UHF, the VHF, and the L and S communication bands.

For the VHF band (30-174 MHz), the band separation circuit 76A shown in FIG. 6A provides a full band signal at the VHF band and a selected sub-band signal of a portion of the VHF band. A full band circuit 78 receives the full band signal and a sub-band circuit 80 receives the selected sub-band signal.

For the UHF band (225-941 MHz), a first and a second band separation circuit 76B shown in FIG. 6B is used to separate the UHF band into a lower UHF band, e.g. 225-450 MHz, and an upper UHF band, e.g. 470-941 MHz. The first band separation circuit provides the lower UHF band signal and a selected sub-band signal of a portion of the lower UHF band. The second band separation circuit provides the upper UHF band signal and a selected sub-band signal of a portion of the upper UHF band. For the lower UHF band, a full band circuit receives the lower UHF band signal and a sub-band circuit receives the selected sub-band signal of the lower UHF band. For the upper UHF band, a full band circuit receives the upper UHF band signal and a sub-band circuit receives the selected sub-band signal of the upper UHF band.

For the L&S bands (1250-2700 MHz), a first and a second band separation circuit 76B shown in FIG. 6B is used to separate the L&S bands into a L band, e.g. 1250-1850 MHz, and a S band, e.g. 2050-2700 MHz. The first band separation circuit provides the L band signal and a selected sub-band signal of a portion of the L band. The second band separation circuit provides the S band signal and a selected sub-band signal of a portion of the S band. For the L band, a full band circuit receives the L band signal and a sub-band circuit receives the selected sub-band signal of the L band. For the S band, a full band circuit receives the S band signal and a sub-band circuit receives the selected sub-band signal of the S band.

The benefit of this solution with parallel full band and sub-band paths in each band is that it allows the full band receivers to be able to apply AGC to receive signals S1 and S3 in this case, while the sub-band filtering is applied to the sub-band path to receive the small signal, S2, simultaneously.

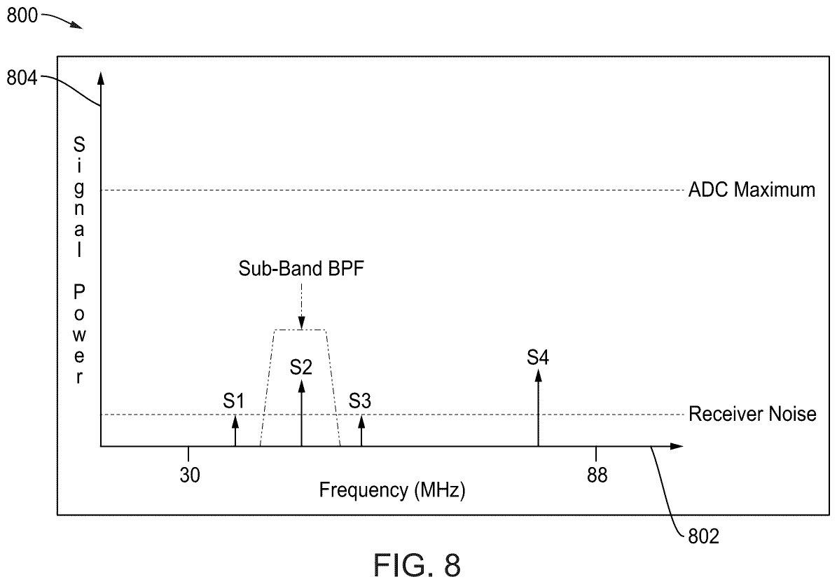

FIG. 8 illustrates a graph 800 showing the sub-band filtering ahead of the ADC reduces S4, along with other channel signals S1 and S3 while preserving the SNR of S2. Axis 802 relates to the frequency in MHz. Axis 804 relates to signal power. By maintaining both the full band circuit and the sub-band circuit to the MFP, the MFP can process both simultaneously and preserve all 3 desired receive signals.

The sub-band circuits can also be scaled beyond one per receive band by expanding the splitter to a 3 or more-way split and increasing the LNA gain to compensate for the additional splitter loss.

While the present disclosure has been particularly described, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present disclosure.

What is claimed is:

1. A multi-band filtering transceiver comprising:
a multi-band antenna;
a transceiver switch having a first end coupled to the multi-band antenna, a transmission port, and a receiving port;
transmission circuitry coupled to the transmission port;
receive circuitry operative to receive an entire frequency band, coupled to the receiving port, the receive circuitry including,
a bandpass filter coupled to the receiving port of the transceiver switch,
a low noise amplifier having an input coupled to the bandpass filter,
a band separation circuit coupled to an output of the low noise amplifier, operative to output a full spectrum signal corresponding to the entire frequency band and a first sub-band signal corresponding to a first portion the entire frequency band,
a full band circuit, coupled to the band separation circuit, operative to receive the full spectrum signal, and
a first sub-band circuit, coupled to the band separation circuit, operative to receive the first sub-band signal; and
a multiplexer coupled to the transmission circuitry and the receive circuitry, operative to output a signal of interest in accordance with an open standard protocol.

2. The multi-band filtering transceiver of claim 1, wherein the band separation circuit is a replicating splitter filter having a first output to provide the full spectrum signal and a second output to provide the first sub-band signal.

3. The multi-band filtering transceiver of claim 2, the first sub-band circuit comprising:
a bandpass filter coupled to the band separation circuit, operative to pass the first sub-band signal;
an automatic gain control circuit coupled to the bandpass filter, operative to amplify the first sub-band signal; and
an analog-to-digital converter coupled to the automatic gain control circuit and the multiplexer.

4. The multi-band filtering transceiver of claim 1, the bandpass separation circuit further comprising:
a diplexer coupled to the low noise amplifier, operative to output the first portion of the entire frequency band and a second portion of the entire frequency band;
a first replicating splitter, coupled to the diplexer, having a first output to provide the first sub-band signal and a second output to provide a signal at a frequency within the first portion; and
a second replicating splitter coupled to the diplexer, having a first output to provide a second sub-band signal at the second portion and a second output to provide a signal at a frequency within the second portion.

5. The multi-band filtering transceiver of claim 2, comprising:
the first sub-band circuit including,
a first bandpass filter coupled to the band separation circuit, operative to pass the first sub-band signal,
a first automatic gain control circuit coupled to the bandpass filter, operative to amplify the first sub-band signal, and
a first analog-to-digital converter coupled to the automatic gain control circuit and the multiplexer; and
a second sub-band circuit including,
a second bandpass filter coupled to the bandpass separation circuit, operative to pass the second sub-band signal,
a second automatic gain control circuit coupled to the second bandpass filter, operative to amplify the second sub-band signal, and
a second analog-to-digital converter coupled to the second automatic gain control circuit and the multiplexer.

6. The multi-band filtering transceiver of claim 5, wherein the multi-band antenna is a tri-band antenna that enables four simultaneous communication bands.

7. The multi-band filtering transceiver of claim 6, wherein the four simultaneous communication bands are VHF (30-174 MHz), UHF (225-450 MHz or 470-941 MHz), L-Band (1250-1850 MHz), S-Band (2050-2700 MHz).

8. The multi-band filtering transceiver of claim 5, wherein the first sub-band range is the L-Band and the second sub-band range is the S-Band.

9. The multi-band filtering transceiver of claim 1 wherein the open standard protocol is selected from a group consisting of VITA 49.2 and MORA 2.5.

10. A co-sited transceiver system comprising:
N transceivers, wherein N>1, at least one of the N transceivers including,
a multi-band antenna;
a transceiver switch having a first end coupled to the multi-band antenna,
a transmission port, and a receiving port;
transmission circuitry coupled to the transmission port;
receive circuitry operative to receive an entire frequency band, coupled to the receiving port, the receive circuitry including,
a bandpass filter coupled to the receiving port of the transceiver switch,
a low noise amplifier having an input coupled to the bandpass filter,
a band separation circuit coupled to an output of the low noise amplifier, operative to output a full spectrum signal corresponding to the entire frequency band and a first sub-band signal corresponding to a first portion the entire frequency band,
a full band circuit, coupled to the band separation circuit, operative to receive the full spectrum signal, and
a first sub-band circuit, coupled to the band separation circuit, operative to receive the first sub-band signal;
a multiplexer coupled to the transmission circuitry and the receive circuitry, operative to output a signal of interest in accordance with an open standard protocol;
a switch coupled to the multiplexer, operative to switch between transmission circuitry and receive circuitry; and
a multi-function processor coupled to the switch, the full band circuit, and the first sub-band circuit, operative to alter signal strength of the full spectrum signal and the first sub-band signal.

11. The co-sited antenna system of claim 10, wherein the band separation circuit is a replicating splitter filter having a first output to provide the full spectrum signal and a second output to provide the first sub-band signal.

12. The co-sited antenna system of claim 10, the first sub-band circuit comprising:
a bandpass filter coupled to the band separation circuit, operative to pass the first sub-band signal;
an automatic gain control circuit coupled to the bandpass filter, operative to amplify the first sub-band signal; and
an analog-to-digital converter coupled to the automatic gain control circuit and the multiplexer.

13. The co-sited antenna system of claim 12, the bandpass separation circuit further comprising:
a diplexer coupled to the low noise amplifier, operative to output the first portion of the entire frequency band and a second portion of the entire frequency band;
a first replicating splitter, coupled to the diplexer, having a first output to provide the first sub-band signal and a second output to provide a signal at a frequency within the first portion; and
a second replicating splitter coupled to the diplexer, having a first output to provide a second sub-band signal at the second portion and a second output to provide a signal at a frequency within the second portion.

14. The co-sited antenna system of claim 13, comprising:
the first sub-band circuit including,
a first bandpass filter coupled to the band separation circuit, operative to pass the first sub-band signal,
a first automatic gain control circuit coupled to the bandpass filter, operative to amplify the first sub-band signal, and
a first analog-to-digital converter coupled to the automatic gain control circuit and the multiplexer; and
a second sub-band circuit including,
a second bandpass filter coupled to the bandpass separation circuit, operative to pass the second sub-band signal,
a second automatic gain control circuit coupled to the second bandpass filter, operative to amplify the second sub-band signal, and
a second analog-to-digital converter coupled to the second automatic gain control circuit and the multiplexer.

15. The co-sited antenna system of claim 10, wherein the multi-band antenna is a tri-band antenna that enables four simultaneous communication bands, wherein the four simultaneous band are VHF (30-174 MHz), UHF (225-450 MHz or 470-941 MHz), L-Band (1250-1850 MHz), S-Band (2050-2700 MHz).

16. The co-sited antenna system of claim 15, wherein the first sub-band range is the L-Band and the second sub-band range is the S-Band.

17. A receiving method for a transceiver comprising:
receiving a full band signal corresponding to an entire frequency band;
separating the full band signal to provide a full spectrum signal corresponding to the entire frequency band and a first sub-band signal corresponding to a first portion the entire frequency band; and
simultaneously transmitting the full spectrum signal and the first sub-band signal to a multi-function processor;
wherein the transceiver is operative to output a signal of interest in accordance with an open standard protocol.

18. The receiving method for a transceiver of claim 17, separating the full band signal comprising:
producing the first portion band signal that corresponds to a first portion of the entire frequency band;
producing the first sub-band signal that corresponds to a band within the first portion of the frequency band;
simultaneously transmitting the first portion band signal and the first sub-band signal;
producing a second portion band signal that corresponds to a second portion of the entire frequency band;
producing the second sub-band signal that corresponds to a band within the second portion of the frequency band; and
simultaneously transmitting the second portion band signal and the second sub-band signal.

19. The receiving method for a transceiver of claim 18, wherein:
the multi-band antenna is a tri-band antenna that enables four simultaneous communication bands; and
the four simultaneous communication bands are VHF (30-174 MHz), UHF (225-450 MHz or 470-941 MHz), L-Band (1250-1850 MHz), S-Band (2050-2700 MHz).

20. The receiving method for a transceiver of claim 19, wherein the first sub-band range is the L-Band and the second sub-band range is the S-Band.
